(19) United States
(12) Patent Application Publication
(10) Pub. No.: US 2026/0190408 A1
(43) Pub. Date: Jul. 2, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Shih-Cheng Chen, New Taipei City (TW); Wen-Ting Lan, Hsinchu City (TW); Jung-Hung Chang, Changhua County (TW); Tsung-Han Chuang, Tainan City (TW); Kuo-Cheng CHIANG, Hsinchu County (TW)

(73) Assignee: Taiwan Semiconductor Manufacturing Company, Ltd., Hsinchu (TW)

(21) Appl. No.: 19/001,557

(22) Filed: Dec. 26, 2024

(51) Int. Cl. H10D 62/13; H01L 21/762; H10D 30/43; H10D 30/67; H10D 62/00; H10D 62/10; H10D 64/66

(52) U.S. Cl. CPC H10D 62/151; H10D 62/021; H10D 64/675; H10W 10/014; H10W 10/17; H10D 30/43; H10D 30/6735; H10D 30/6757; H10D 62/121

(57) ABSTRACT

A semiconductor device includes a semiconductor substrate including a first semiconductor protrusion and a second semiconductor protrusion, a first S/D structure disposed on the first semiconductor protrusion, a second S/D structure disposed on the second semiconductor protrusion and laterally spaced apart from the first S/D structure, and a first isolation structure disposed on the semiconductor substrate and laterally interposed between the first and second semiconductor protrusions. The first isolation structure includes a recessed top surface toward the semiconductor substrate, and the recessed top surface of the first isolation structure includes slopes that vary randomly across the recessed top surface in a cross-sectional view.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-14B illustrate schematic various views of intermediate steps during a process for forming a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” may indicate a value of a given quantity that varies within a process variation known by those skilled in relevant art(s) in light of the teachings herein, for example, these terms may indicate a value of a given quantity that varies within 20 % of the value (e.g., ±1 %, ±2 %, ±3 %, ±4 %, ±5 %, ±10 %, ±20 % of the value). These values are merely examples and are not intended to be limiting. The terms “about” and “substantially” may refer to a percentage of the values as interpreted by those skilled in relevant art(s) in light of the teachings herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The embodiments of the disclosure describe a manufacturing process of a semiconductor device (or a portion of a nanostructure transistor device). The nanostructure transistor device (also referred to as a gate-all-around (GAA) transistor device) may include a gate structure wrapping around the perimeter of one or more nanostructures (i.e. channel regions) for improved control of channel current flow. The embodiments are not limited in this context. The semiconductor device may be included in microprocessors, memories, and/or other integrated circuits (IC). Accordingly, it is understood that additional processes may be provided before, during, and after the illustrated method, and that some other processes may only be briefly described herein. Also, the structures illustrated in the drawings are simplified for a better understanding of the concepts of the present disclosure. For example, although the figures illustrate the structure of the semiconductor device, it is understood the semiconductor device may be part of an IC that further includes a number of other devices such as resistors, capacitors, inductors, fuses, etc.

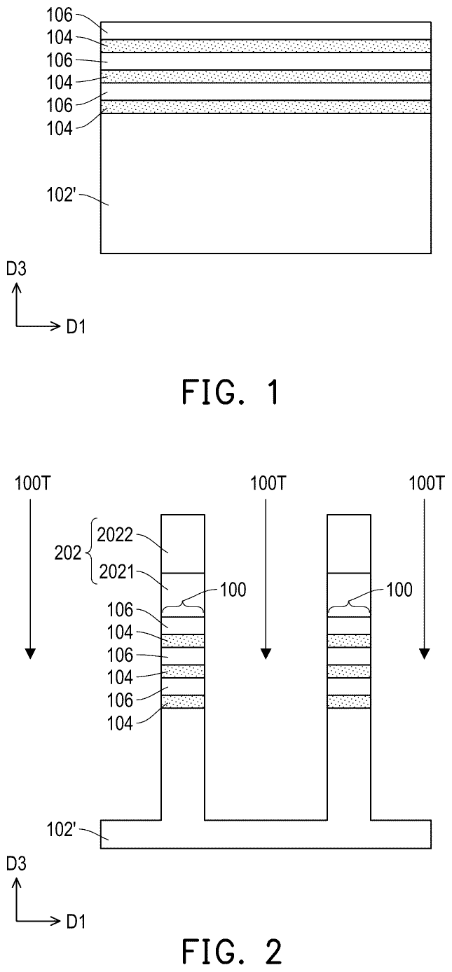

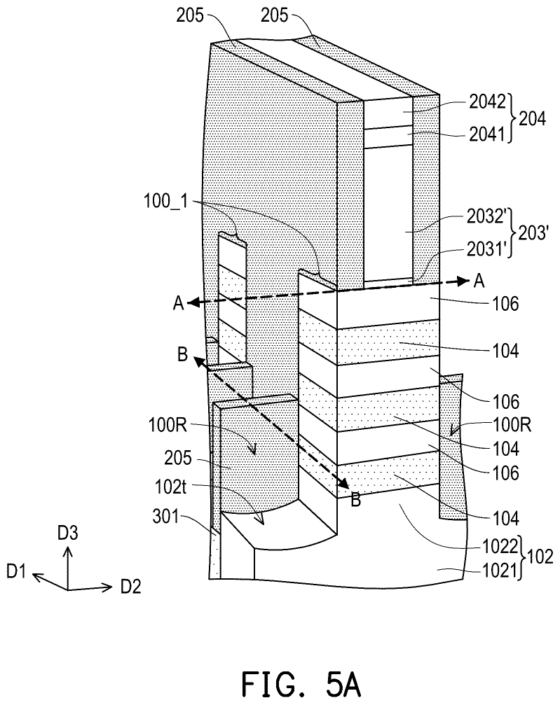

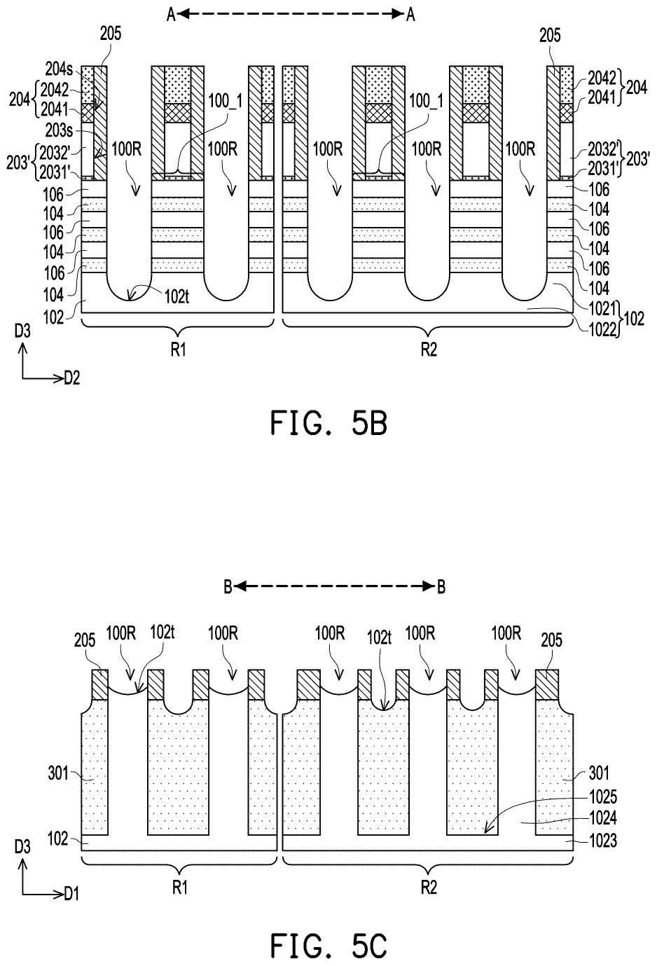

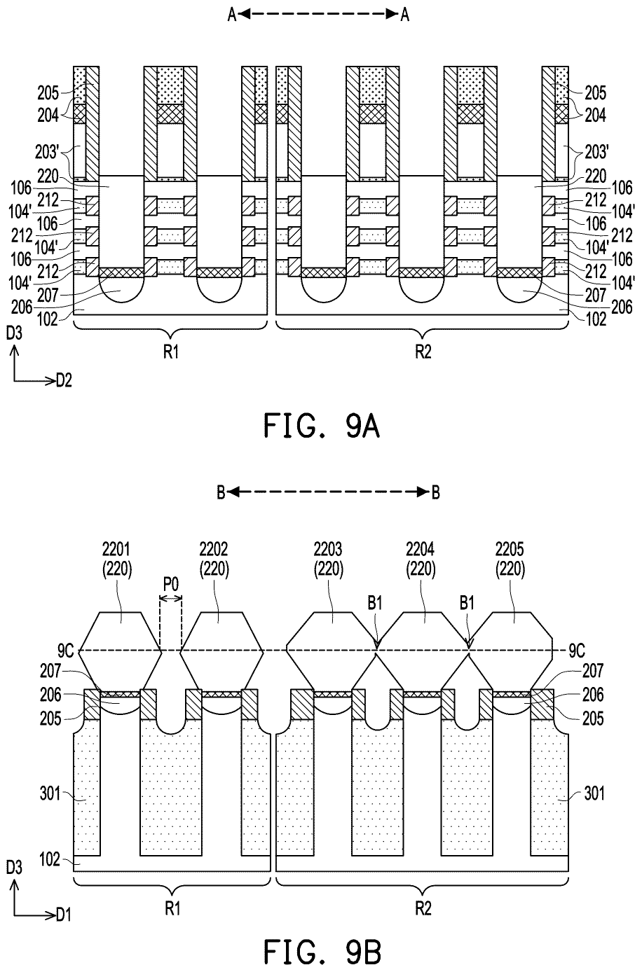

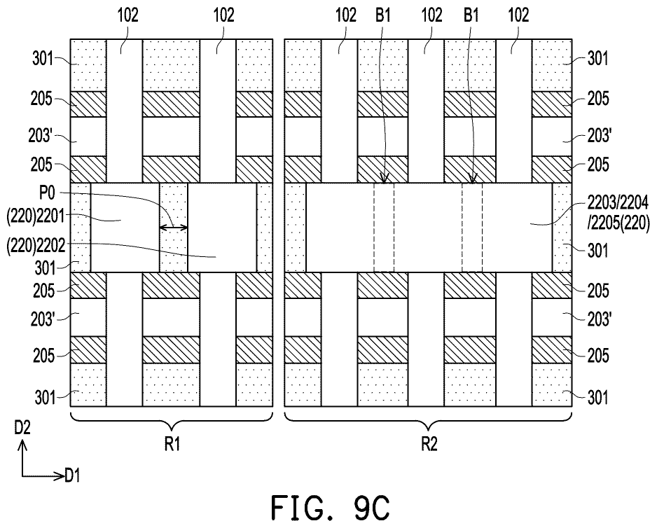

FIGS. 1-14B illustrate schematic various views of intermediate steps during a process for forming a semiconductor device, in accordance with some embodiments. For clarity of illustrations, in the drawings are illustrated the directions (e.g., D1, D2 and D3) of the coordinate system according to which the views are oriented, where the directions D1, D2 and D3 are substantially perpendicular to one another. For example, the direction D1 is x direction, the direction D2 is y direction, and the direction is z direction. It should be noted that FIG. 5A is a schematic perspective view of the structure, FIGS. 5B, 6A, 7A, 8A, 9A, 10A, 11A, 12A, 13A, and 14A are schematic cross-sectional views taken along the line A-A in FIG. 5A, and FIGS. 5C, 6B, 7B, 8B, 9B, 10B, 11B, 12B, 13B, and 14B are schematic cross-sectional views taken along the line B-B in FIG. 5A. In addition, FIGS. 9C, 10C, 11C, 12C are schematic plan views corresponding to their cross-sectional views, in accordance with some embodiments.

Referring to FIG. 1, a stack of first semiconductor layers 104 and second semiconductor layers 106 may be formed on a semiconductor substrate 102′. In some embodiments, the semiconductor substrate 102′ includes a crystalline silicon substrate or a bulk silicon substrate (e.g., wafer). In some embodiments, the semiconductor substrate 102′ is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 102′ includes a semiconductor-on-insulator (SOI) substrate. The semiconductor substrate 102′ may include various doped regions (not individually shown) doped with p-type or n-type dopants, where the doped regions may be configured for an n-type field effect transistor (FET), or alternatively, configured for a p-type FET.

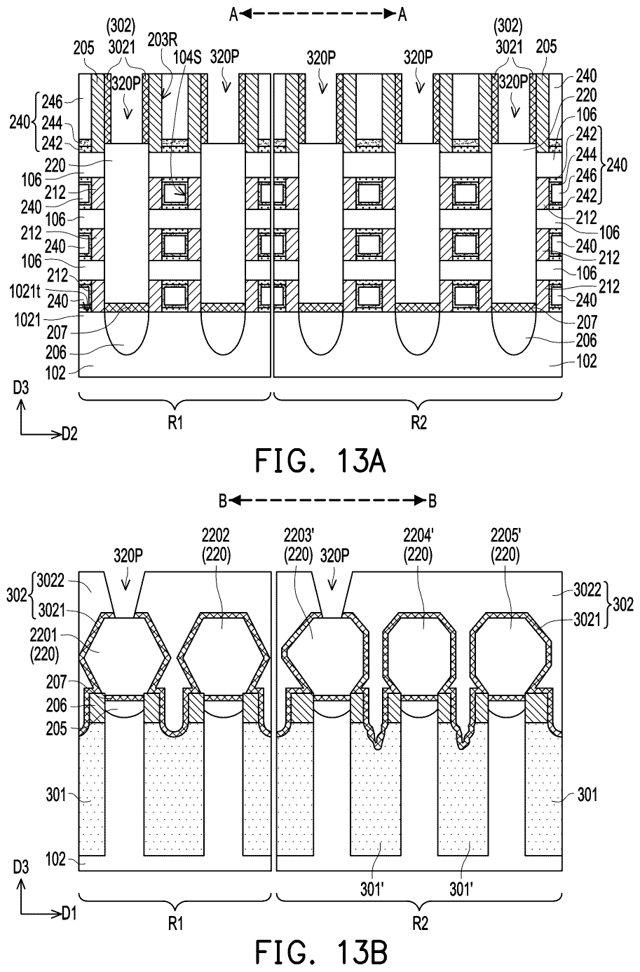

With continued reference to FIG. 1, the first semiconductor layers 104 and the second semiconductor layers 106 may be alternately stacked upon one another (e.g., along the direction D3) to form a stack. The first semiconductor layers 104 may be considered sacrificial layers in the sense that they are removed in the subsequent process (see FIG. 13A). In some embodiments, the bottommost one of the first semiconductor layers 104 is formed on the semiconductor substrate 102′, with the remaining second and first semiconductor layers (106 and 104) alternately stacked on top. However, either the first semiconductor layer 104 or the second semiconductor layer 106 may be the bottommost layer (or the layer most proximate from the semiconductor substrate 102′), and either the first semiconductor layer 104 or the second semiconductor layer 106 may be the topmost layer (or the layer most distanced to the semiconductor substrate 102′). The disclosure is not limited by the number of stacked semiconductor layers (e.g., 104 and 106).

With continued reference to FIG. 1, the first semiconductor layers 104 and the second semiconductor layers 106 may have different materials (or compositions) that may provide for different oxidation rates and/or different etch selectivity between the layers. For example, the second semiconductor layers 106 are formed of the same material as the semiconductor substrate 102′, while the first semiconductor layers 104 may be formed of a different material which may be selectively removed with respect to the material of the semiconductor substrate 102′ and the second semiconductor layers 106. In some embodiments, the material of the first semiconductor layers 104 includes silicon germanium (SiGe). In some embodiments, the second semiconductor layers 106 include silicon, (Si) where each of the second semiconductor layers 106 may be undoped or substantially dopant-free. However, the disclosure is not limited thereto, and other suitable material, or other combinations of materials for which selective etching is possible are contemplated within the scope of the disclosure. The second semiconductor layers 106 may be semiconductor nanosheets and may be considered as channel regions in the subsequent processes. The terms “semiconductor nanosheets” and “channel regions” may be used interchangeably herein.

Referring to FIG. 2 and with reference to FIG. 1, a portion of the stack of first semiconductor layers 104 and second semiconductor layers 106 and the underlying portion of the semiconductor substrate 102′ may be removed to form trenches 100T, thereby defining a fin structure 100 between adjacent trenches 100T. Each trench 100T may be disposed between adjacent two of the fin structures 100. The lengthwise direction (e.g., the direction D2 labeled in FIG. 5A) of the fin structure 100 may be referred to as the X-cut direction. In some embodiments, the fin structure 100 is formed by patterning the stack of first semiconductor layers 104 and second semiconductor layers 106 and the underlying semiconductor substrate 102′ by using, e.g., lithography and etching, or other suitable techniques.

In some embodiments, a mask layer 202 is first formed over the top of the stack, e.g., on the topmost one of the second semiconductor layers 106. The mask layer 202 may be a single layer or include more than one sublayer (e.g., a first mask sublayer 2021 overlying the fin structure 100 and a second mask sublayer 2022 overlying the first mask sublayer 2021). In some embodiments, each of the sublayers (e.g., 2021 and 2022) is formed of a semiconductor material similar to the material of first and second semiconductor layer (e.g., 104 or 106) or is formed of different dielectric materials. The mask layer 202 may be used to pattern exposed portions of the stack of first semiconductor layers 104 and second semiconductor layers 106 and the underlying semiconductor substrate 102′. For example, the fin structure 100 is formed by etching the trenches 100T at exposed portions of the stack of first semiconductor layers 104 and second semiconductor layers 106 and the semiconductor substrate 102′ which are not covered by the mask layer 202.

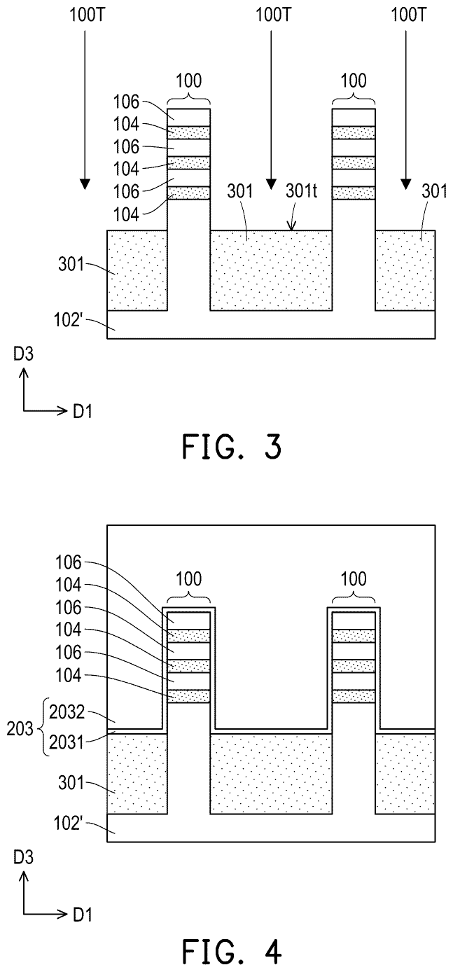

Referring to FIG. 3 and with reference to FIG. 2, a plurality of isolation structures 301 (also referred to as shallow trench isolation (STI) structures) may be formed in lower portions of the trenches 100T. For example, the isolation structures 301 extend at opposing sides of a lower portion of the semiconductor substrate 102′. In some embodiments, each of the isolation structures 301 is disposed between adjacent two of the fin structures 100 and covers a sidewall of a lower portion of the respective fin structure 100. The isolation structures 301 may each be formed of one or more insulation material(s) (e.g., an oxide, a Si-based oxide (e.g., SiOC, SiOCN, or the like), a nitride, the like, any other suitable material(s), combinations thereof, etc.) which may electrically isolate neighboring fin structures 100 from each other.

With continued reference to FIG. 3 and FIG. 2, the isolation structures 301 may be formed by initially depositing insulation material(s) in and on the respective trench 100T, removing portions of the insulation material(s) outside the respective trench 100T using a planarization process such as CMP process and recessing the insulation material(s) using an acceptable etching process, such as one that is selective to the material(s) of the isolation structures 301. During the recessing, the first mask sublayer 2021 and the second mask sublayer 2022 left on the fin structures 100 may serve as the etch masks. The isolation structures 301 may be recessed, and thus the fin structure 100 is protruded from the neighboring isolation structures 301. The top surfaces 301t of the isolation structures 301 may be a flat surface, a curved (e.g., convex or concave) surface, or combinations thereof, depending on the etching process. After (or during) the formation of the isolation structures 301, the first mask sublayer 2021 and the second mask sublayer 2022 may be removed from the fin structures 100, and the topmost one of the fin structure 100 may then be exposed.

Referring to FIG. 4 and with reference to FIG. 3, a dummy gate structure 203 may be formed on the fin structures 100. The dummy gate structure 203 may also be formed in the trenches 100T and on the isolation structures 301. The dummy gate structure 203 may have the lengthwise direction along the direction D1 which is substantially perpendicular to the lengthwise direction of the respective fin structure 100. For example, the dummy gate structure 203 includes a dummy dielectric layer 2031 covering the fin structures 100 and the isolation structures 301 and a dummy gate layer 2032 formed on the dummy dielectric layer 2031. In some embodiments, the dummy dielectric layer 2031 covers the top surfaces 301t of the isolation structures 301 and may extend between the dummy gate layer 2032 and the isolation structures 301. The dummy dielectric layer 2031 may be or include silicon oxide, silicon nitride, a combination thereof, or the like, and may be deposited according to acceptable techniques. The dummy gate layer 2032 may be a conductive or non-conductive material and may be selected from a group including amorphous silicon, polysilicon, poly-crystalline silicon-germanium, metallic oxides, and metals, and may be formed by using physical vapor deposition (PVD), chemical vapor deposition (CVD), atomic layer deposition (ALD), sputtering, or other suitable techniques.

Referring to FIGS. 5A-5C and with reference to FIG. 4, a mask layer 204 may be formed on the dummy gate structure 203. The mask layer 204 may be a single mask layer or include multiple sublayers formed of different materials including silicon nitride, silicon oxynitride, or the like. In the illustrated embodiment, the mask layer 204 includes a first mask sublayer 2041 overlying the dummy gate structure 203 and a second mask sublayer 2042 overlying the first mask sublayer 2041. For example, one or more mask material(s) may be initially formed and then patterned using acceptable lithography and etching techniques to form the mask layer 204. Next, the pattern of the mask layer 204 may be transferred to the dummy gate structure 203 to form the patterned dummy gate structure 203′ including the patterned dummy gate layer 2032′ and the patterned dummy dielectric layer 2031′.

With continued reference to FIGS. 5A-5C and FIG. 4, a sidewall spacer layer 205 may then be formed on sidewalls of the mask layer 204 and the patterned dummy gate structure 203′. The sidewall spacer layer 205 may be a single layer or may include multiple sublayers formed of different materials including SiCN, SiOC, SiOCN, or the like. The sidewall spacer layer 205 may be deposited by thermal oxidation or deposited by CVD, ALD, PVD, or the like. The sidewall spacer layer 205 may act to self-align subsequently formed source/drain (S/D) regions, as well as to protect sidewalls of the respective fin structure 100 during subsequent processing. In some embodiments, the sidewall spacer layer 205 is disposed on the sidewalls 203s of the patterned dummy gate structure 203′ and extends to cover sidewalls 204s of the mask layer 204. In some embodiments, a fin spacer 205F is disposed on the sidewalls of the respective fin structure 100. The fin spacer 205F may be formed simultaneously with the sidewall spacer layer 205 and include the same material as the sidewall spacer layer 205.

With continued reference to FIGS. 5A-5C and FIG. 4, a portion of the respective fin structure 100 and a portion of the semiconductor substrate 102′ underlying the portion of the respective fin structure 100 may be removed to form recesses 100R and a respective etched fin structure 100_1 between two adjacent recesses 100R. The S/D regions will be subsequently formed in the recesses 100R, and the recesses 100R may be referred to as S/D recesses. The recesses 100R may be formed by etching the sidewall spacer layer 205, the underlying fin structures 100, and the underlying semiconductor substrate 102′ using suitable etching processes (e.g., anisotropic etching or the like). The respective recess 100R may extend through the respective fin structure 100 to form the etched fin structure 100_1. In some embodiments, outer sidewalls of the sidewall spacer layer 205 are substantially aligned with sidewalls of the etched fin structure 100_1, as shown in FIGS. 5A-5B. In some embodiments, the respective recess 100R extends further into the underlying semiconductor substrate 102′ to form a semiconductor substrate 102.

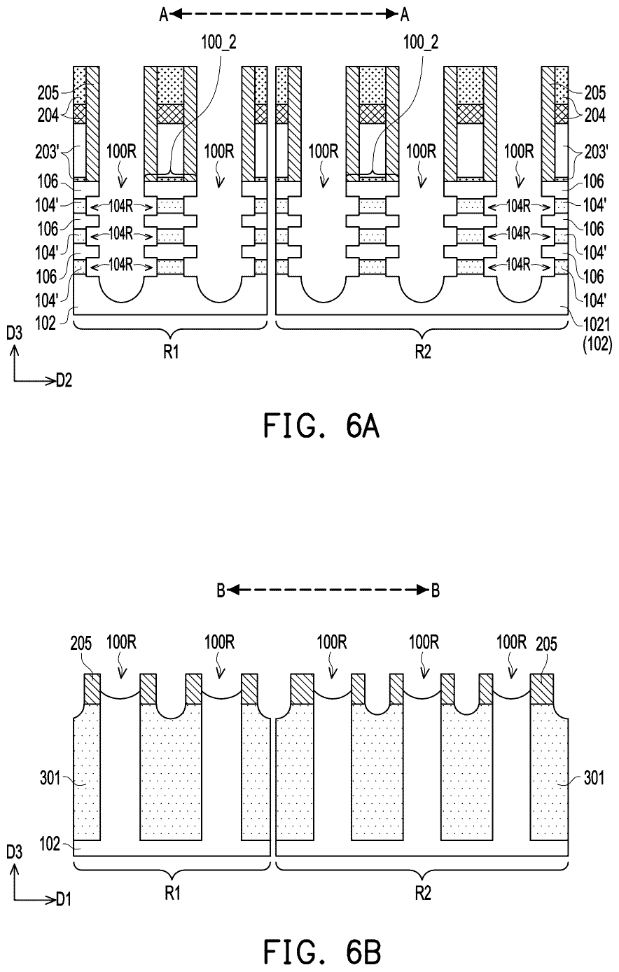

Still referring to FIGS. 5B-5C, the semiconductor substrate 102 may include bottom fin portions (or a base portion) 1021 and recess portions 1022 laterally connected to adjacent two of the bottom fin portions 1021, as shown in FIG. 5B. The respective recess portion 1022 may have a top surface 102t which can be a flat surface, a curved (e.g., concave) surface, or combinations thereof, depending on the etching process. In the cross-sectional view of FIG. 5C, the semiconductor substrate 102 may include a planar portion 1023 and protruding portions 1024 on the planar portion 1023. The semiconductor substrate 102 may include protruding portions 1024 and recessed portions 1025 alternately arranged along the first direction D1. The isolation structures 301 may be formed on the planar portion 1023 which corresponds to the recessed portions 1025. The cross-sectional views of FIGS. 5B-5C may each show two different regions (e.g., the first region R1 and the second region R2). At this stage and the following steps (e.g., FIGS. 6A-6B, FIGS. 7A-7B, and FIGS. 8A-8B), the first region R1 and the second region R2 are substantially the same. After forming the epitaxial structures, the structure in the first region R1 is different from the structure in the second region R2 as will be described later in accompanying with FIGS. 9A-9B.

Referring to FIGS. 6A-6B and with reference to FIGS. 5B-5C, portions of the first semiconductor layers 104 exposed by the recesses 100R may be removed in the lateral direction (e.g., the direction D2) to form a respective etched fin structure 100_2 having etched first semiconductor layers 104′. The removal may be performed by using, e.g., isotropic etching processes or other suitable removal techniques. For example, the etchant of the selective etching process is chosen so that the portions of the first semiconductor layers 104 are removed to form lateral recesses 104R, while the second semiconductor layers 106 remain substantially intact during the etching. The respective etched first semiconductor layer 104′ may be laterally recessed from the sidewalls of the underlying (or overlying) second semiconductor layer 106. Although sidewalls of the etched first semiconductor layers 104′ adjacent the lateral recesses 104R are illustrated as being straight in FIG. 6A, the sidewalls of the etched first semiconductor layers 104′ may be concave or convex. Note that the etching of the first semiconductor layers 104 is not shown in the cross-sectional view of FIG. 6B so that the structure in FIG. 6B is the same as the structure shown in FIG. 5C.

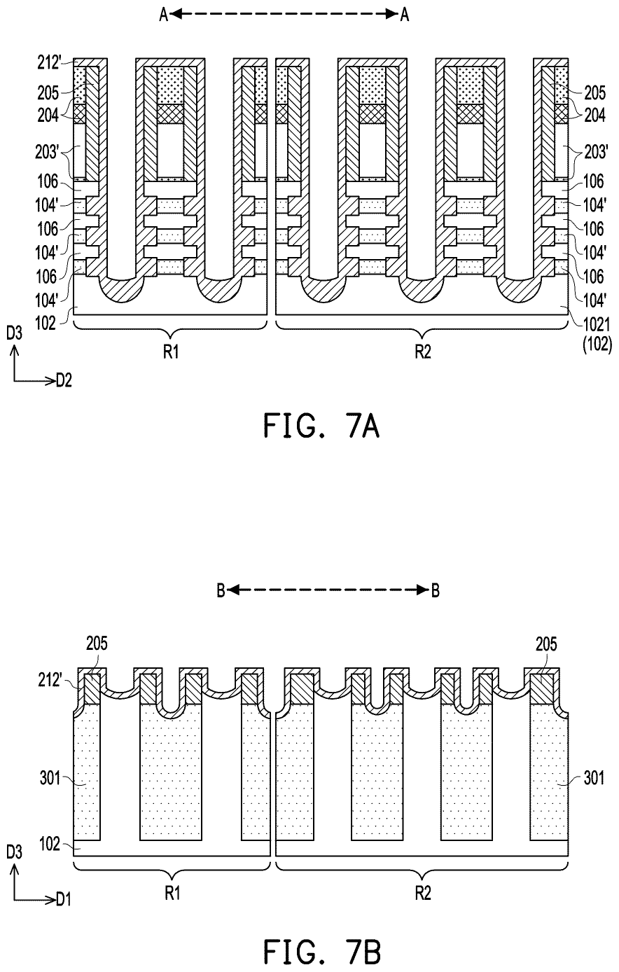

Referring to FIGS. 7A-7B and with reference to FIGS. 6A-6B, a spacer material 212′ may be formed on the structures shown in FIGS. 6A-6B. For example, the spacer material 212′ is formed of SiOCN, SiOC, SiCN, combination thereof, or any other type of dielectric material(s), and may be deposited using, e.g., a conformal deposition process or any suitable deposition process. As shown in the cross-sectional view of FIG. 7A, the spacer material 212′ may cover the exposed surfaces of the mask layer 204, the sidewall spacer layer 205, the stack of the second semiconductor layers 106 and the etched first semiconductor layers 104′, and the semiconductor substrate 102. In some embodiments, the lateral recesses 104R are filled with the spacer material 212′. As shown in the cross-sectional view of FIG. 7B, the spacer material 212′ may conformally cover the exposed surfaces of the sidewall spacer layer 205, the isolation structures 301, and the semiconductor substrate 102.

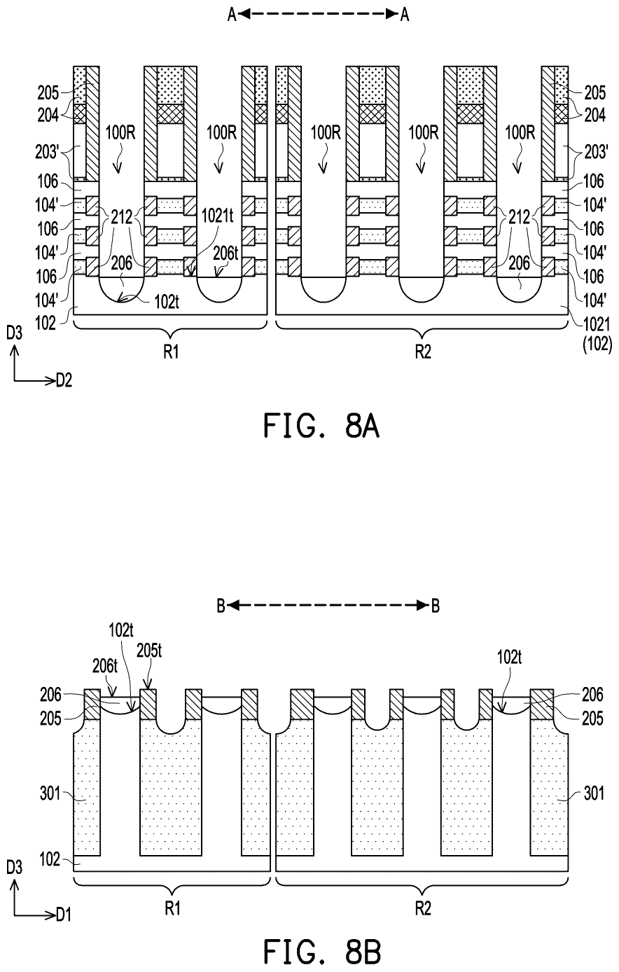

Referring to FIGS. 8A-8B and with reference to FIGS. 7A-7B, a portion of the spacer material 212′ may be removed to form inner sidewall spacers 212 in the lateral recesses 104R (see FIG. 6A) alongside the etched first semiconductor layers 104′. For example, after the deposition of the spacer material 212′, one or more etching process may be performed on the spacer material 212′ to remove excess spacer materials on the sidewalls of the etched fin structure 100_2 (see FIG. 6A) and on the exposed surfaces of the semiconductor substrate 102, the mask layer 204, the sidewall spacer layer 205, and the isolation structures 301. The inner sidewall spacers 212 may then be formed along the etched ends of each of the etched first semiconductor layers 104′ and along respective ends of each of the etched first semiconductor layers 104′ and the second semiconductor layers 106. In some embodiments, the inner sidewall spacers 212 are formed of a material different than the material of the sidewall spacer layer 205. In one embodiment, the inner sidewall spacer 212 contains a dielectric constant different from the dielectric constant of sidewall spacer layer 205. In another embodiment, the inner spacer 212 contains a material composition different from the material composition of the sidewall spacer layer 205. The sidewall spacer layer 205 may serve as an etch mask during the removal of the excess spacer materials, and thus the outer sidewalls of the sidewall spacer layer 205 may be substantially aligned with outer sidewalls of the underlying second semiconductor layers 106 and outer sidewalls of the inner sidewall spacers 212.

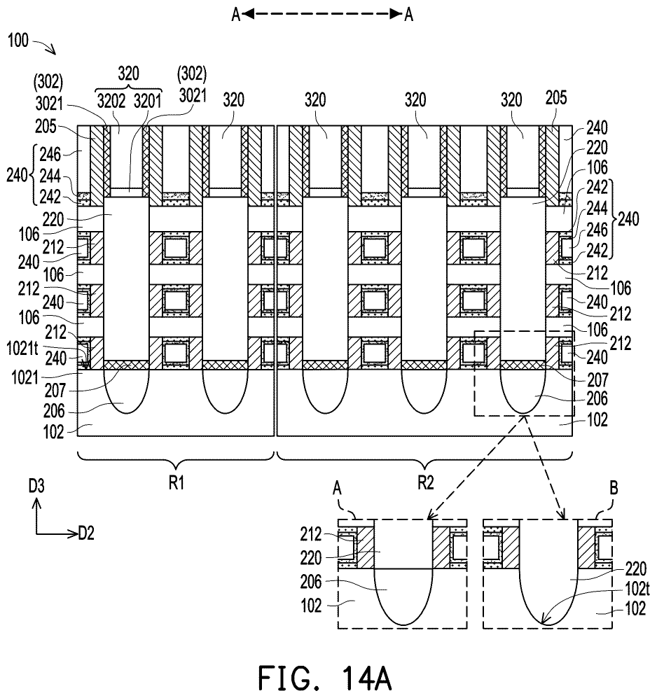

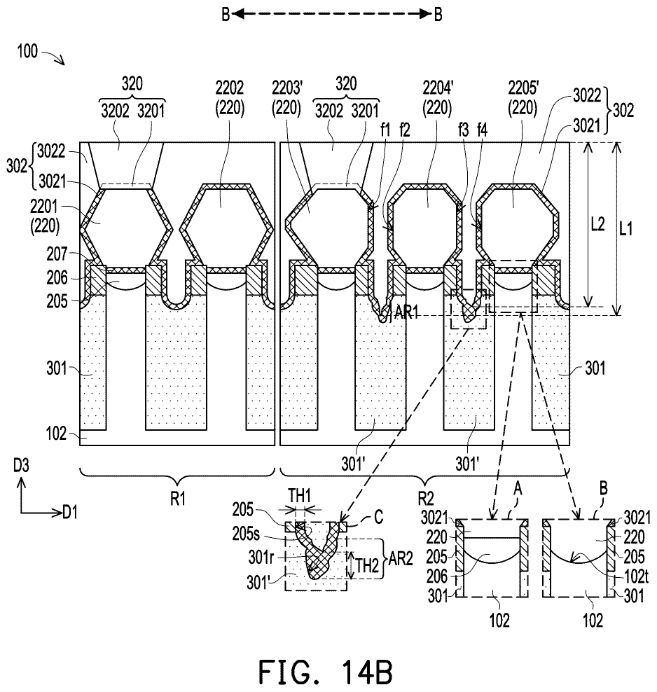

Still referring to FIGS. 8A-8B and with reference to FIGS. 7A-7B, a semiconductor layer 206 is optionally formed in the recesses 100R and on the top surfaces 102t of the bottom fin portions 1021 of the semiconductor substrate 102. In some embodiments, the semiconductor layer 206 is made of one or more semiconductor material(s) such as Si, Ge, SiGe, etc., and may be formed by suitable deposition process such as epitaxially growing or the like. For example, the material of the semiconductor layer 206 is the same as the material of the semiconductor substrate 102 and/or the material of the second semiconductor layer 106. In alternative embodiments, the material of the semiconductor layer 206 is the same as the etched first semiconductor layers 104′. The semiconductor layer 206 may be an undoped region (or substantially dopant-free region). In some embodiments, the doping concentration of the semiconductor layer 206 is lower than the subsequently formed epitaxial structures. As shown in the cross-sectional view of FIG. 8A, the top surface 206t of the semiconductor layer 206 may be substantially leveled with the top surface 1021t of the adjacent one of the bottom fin portions 1021. As shown in the cross-sectional view of FIG. 8B, the top surface 206t of the semiconductor layer 206 may be between the top surface 102t of the semiconductor substrate 102 and the top surface 205t of the sidewall spacer layer 205. Alternatively, the semiconductor layer 206 is omitted as will be described later in accompanying with FIGS. 14A-14B.

Referring to FIGS. 9A-9B and with reference to FIGS. 8A-8B, an insulating layer 207 may be formed on the semiconductor layer 206 and in the recesses 100R. For example, the insulating layer 207 is made of one or more insulating material(s) such as an oxide, a Si-based oxide (e.g., SiOC, SiOCN, or the like), a nitride, a Si-based nitride (e.g., SiCN, or the like), combinations thereof, or any other suitable insulating material. In some embodiments, the semiconductor layer 206 is thicker than the insulating layer 207. In an embodiment, a top surface of the insulating layer 207 is lower than a bottom surface of the bottommost channel 106. As shown in the cross-sectional view of FIG. 9A, the insulating layer 207 overlying the semiconductor layer 206 may be in lateral contact with the bottommost one of the inner sidewall spacers 212. As shown in the cross-sectional view of FIG. 9B, the insulating layer 207 overlying the semiconductor layer 206 may be in lateral contact with the fin spacer 205F but space apart from the sidewall spacer layer 205. Alternatively, the insulating layer 207 is omitted as will be described later in accompanying with FIGS. 14A-14B.

With continued reference to FIG. 9A-9B and with reference to FIGS. 8A-8B, epitaxial structures 220 may be formed on the insulating layer 207 and in the recesses 100R through any suitable deposition process such as epitaxially growing or the like. The epitaxial structures 220 may be coupled to the outer sidewalls of the second semiconductor layers 106 and the inner sidewall spacers 212. The respective epitaxial structure 220 may include a crystalline semiconductor material such as silicon germanium, silicon germanium boron, silicon phosphorous, indium arsenide, indium gallium arsenide, indium antimonide, germanium arsenide, germanium antimonide, indium aluminum phosphide, indium phosphide, any other suitable material, or combinations thereof. The epitaxial structures 220 may be doped with conductive dopants to form S/D structures (or S/D regions). It should be noted that S/D region(s) may refer to a source or a drain, individually or collectively dependent upon the context. In addition, the terms “epitaxial structures” and “S/D regions” may be used interchangeably herein. In some embodiments, the epitaxial structures 220 are doped with different types of dopants. A portion of the epitaxial structures 220 may be configured for an n-type FET, and the other portion of the epitaxial structures 220 may be configured for a p-type FET. In some other embodiments, the epitaxial structures 220 are doped with the same type of dopants (e.g., p-type dopants or n-type dopants) and configured for the same type of FET.

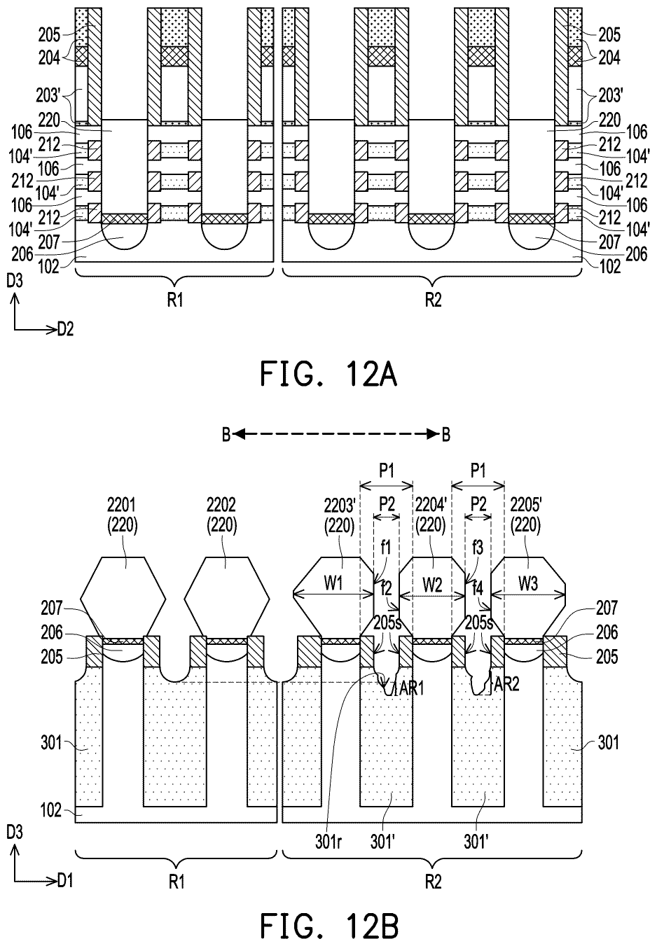

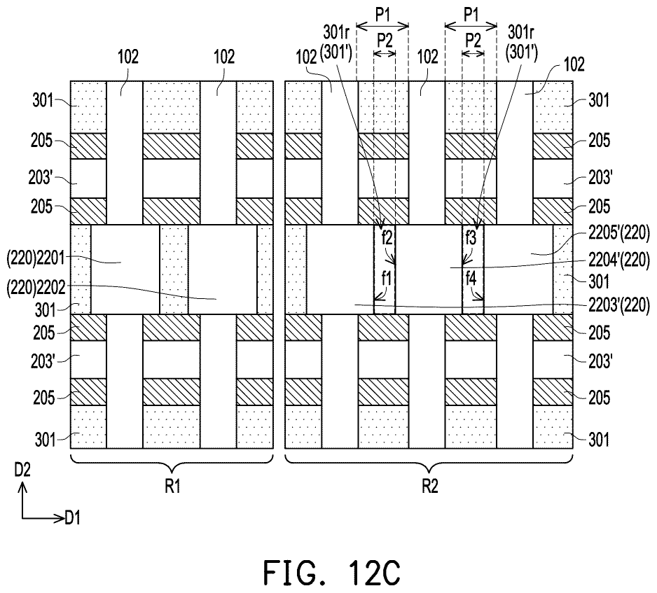

With continued reference to FIGS. 9A-9B and referring to FIG. 9C, in the cross-sectional view of FIG. 9A, the structure in the first region R1 is substantially the same as the structure in the second region R2, while in the cross-sectional view of FIG. 9B, the structure (e.g., epitaxial structures 220) in the first region R1 is different from the structure (e.g., epitaxial structures 220) in the second region R2. FIG. 9C is a plan view of the structure taken along the dashed line 9C-9C in FIGS. 9A-9B. As shown in FIGS. 9B-9C, adjacent epitaxial structures 220 in the first region R1 may be entirely separated from one another, while adjacent epitaxial structures 220 in the second region R2 may be bridged together. This difference may result from process variation of the formation of the epitaxial structures 220 and/or a lateral distance (P1, as shown in FIG. 12B) between tops of the adjacent sidewalls 102s of the protruding portions 1024 of the semiconductor substrate 102. For example, due to the process variation of the formation of the epitaxial structures 220, in the first region R1, the epitaxial structure 2201 may be laterally spaced apart from the epitaxial structure 2202 by a lateral distance P0 measured in the first direction D1, where the lateral distance P0 is non-zero. In the second region R2, at least two of the adjacent epitaxial structures 220 may be laterally connected along the first direction D1 to form a bridged portion B1. In some embodiments, the epitaxial structure 2204 in the second region R2 has one side connected to the epitaxial structure 2203 and the opposing side connected to the epitaxial structure 2205. Although FIG. 9B shows that three epitaxial structures are bridged together, the number of the epitaxial structures having the bridged portion may be two or more than three according to some embodiments. In alternative embodiments (not shown), a lateral distance (P1, as shown in FIG. 12B) between tops of the adjacent sidewalls 102s of the protruding portions 1024 in the first region R1 is different from that in the second region R2 and thus causes the difference of the epitaxial structures 220 in the first and second regions R1, R2. In alternative embodiments (not shown), the epitaxial structures 220 in both first and second regions R1, R2 are laterally connected.

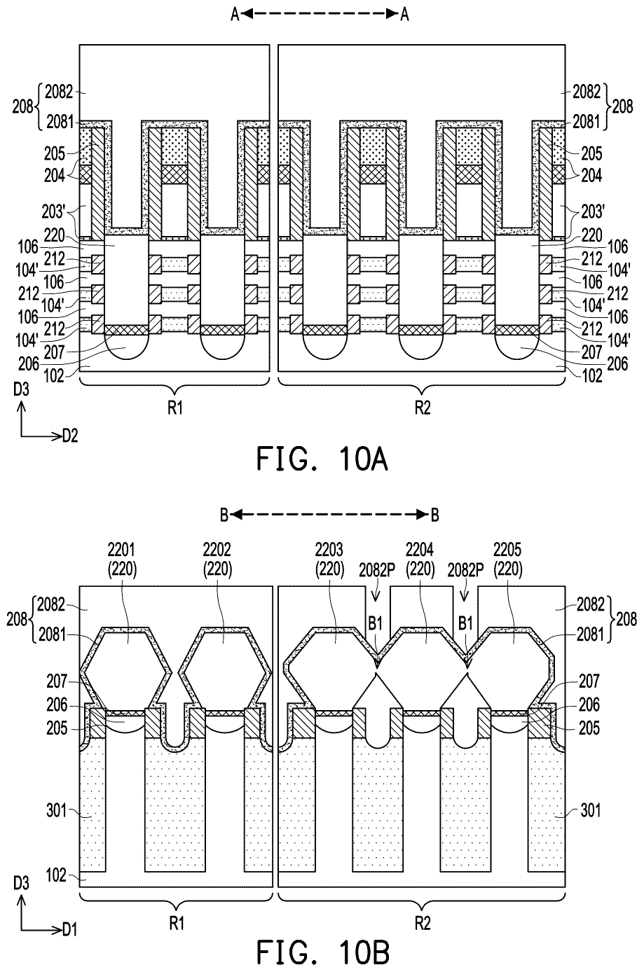

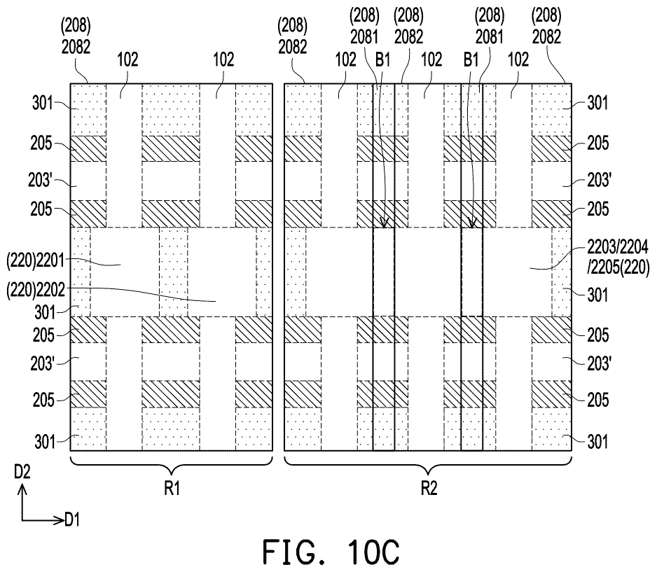

Referring to FIGS. 10A-10C and with reference to FIGS. 9A-9C, a mask structure 208 may be formed on the structures shown in FIGS. 9A-9C. The mask structure 208 may include a hard mask layer 2081 overlying the structures shown in FIGS. 9A-9B and a patterned mask layer 2082 overlying the hard mask layer 2081. In some embodiments, the hard mask layer 2081 includes a material that protects the underlying structure when processing the patterned mask layer 2082. For example, the patterned mask layer 2082 is a photoresist layer. In some embodiments, the patterned mask layer 2082 is formed by forming a photoresist layer and performing an exposure process to the photoresist layer. After the exposure process, a post-baking process may be performed to harden at least a portion of the photoresist layer. A development process may then be performed to remove at least a portion of the photoresist layer. In some embodiments, the patterned mask layer 2082 exposes at least a portion of the underlying hard mask layer 2081.

As shown in the cross-sectional view of FIG. 10A, the hard mask layer 2081 may be conformally formed on the exposed surfaces of the sidewall spacer layer 205, the mask layer 204, and the epitaxial structures 220, and the patterned mask layer 2082 may be formed on the hard mask layer 2081 and fill the trenches directly over the epitaxial structures 220. In the cross-sectional view of FIG. 10A, the structures in the first region R1 and the second region R2 may be covered by the patterned mask layer 2082. As shown in the cross-sectional view of FIG. 10B, the hard mask layer 2081 may be conformally formed on the exposed surfaces of the epitaxial structures (2203, 2204, and 2205), the sidewall spacer layer 205, and the isolation structures 301. In the first region R1 of the cross-sectional view of FIG. 10B, the patterned mask layer 2082 may fully cover the hard mask layer 2081. In the second region R2 of the cross-sectional view of FIG. 10B, since the epitaxial structures (2203, 2204, and 2205) are bridged together, lower surfaces of the epitaxial structures (2203, 2204, and 2205), the sidewall spacer layer 205, and the isolation structures 301 which are blocked by the bridged portions B1 of the epitaxial structures (2203, 2204, and 2205) may not be directly covered by the hard mask layer 2081. The openings 2082P of the patterned mask layer 2082 may be formed in the second region R2 and directly over the bridged portions B1 of the epitaxial structures (2203, 2204, and 2205). For example, portions of the hard mask layer 2081 overlying the bridged portions B1 are exposed by the openings 2082P of the patterned mask layer 2082.

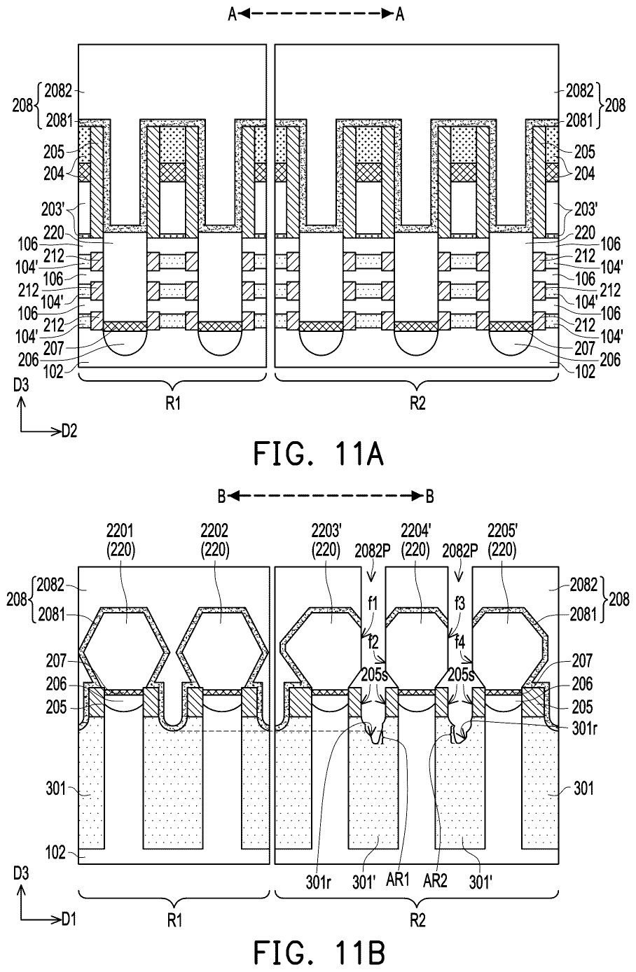

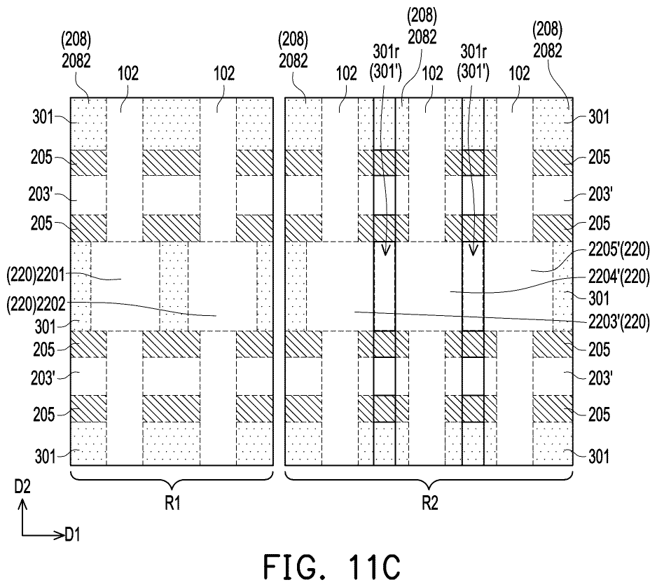

Referring to FIGS. 11A-11C and with reference to FIGS. 10A-10C, the hard mask layer 2081 and the underlying epitaxial structures (2203, 2204, and 2205) may be patterned by using the patterned mask layer 2082. Note that the etching of the hard mask layer 2081 and the epitaxial structures (2203, 2204, and 2205) is not shown in the cross-sectional view of FIG. 11A so that the structure in FIG. 11A is the same as the structure shown in FIG. 10A. In some embodiments, since the hard mask layer 2081 and the epitaxial structures (2203, 2204, and 2205) have different material characterization, the hard mask layer 2081 and the epitaxial structures (2203, 2204, and 2205) are patterned by different etching processes. For example, a first etching process is performed on the hard mask layer 2081 to remove portions of the hard mask layer 2081 exposed by the openings 2082P, so as to transfer the pattern of the patterned mask layer 2082 onto the hard mask layer 2081. The first etching process may include a dry etching process, a wet etching process, or combination thereof. In some embodiments, the first etching process uses a dry etching process that selectively etches the hard mask layer 2081. After the portions of the hard mask layer 2081 exposed by the openings 2082P are removed, a second etching process may be performed to the epitaxial structures (2203, 2204, and 2205) to remove the bridged portions B1 exposed by the openings 2082P. In some embodiments, the second etching process uses a dry etching process that selectively etches the underlying epitaxial structures (2203, 2204, and 2205) and thus the etched facet (e.g., f1, f2, f3, and/or f4) may be substantially flat and substantially vertical to the first direction D1. In alternative embodiments, the second etching process uses a wet etching process that selectively etches the underlying epitaxial structures (2203, 2204, and 2205) and thus the etched facet (e.g., f1, f2, f3, and/or f4) may be rough.

With continued reference to FIGS. 11B-11C and with reference to FIGS. 10B-10C, after the etching, the bridged portions B1 of the epitaxial structures (2203, 2204, and 2205) may be removed to form individual epitaxial structures (2203′, 2204′, and 2205′) that are spaced apart from one another along the first direction D1 and the second direction D2. For example, as shown in the cross-sectional view of FIG. 11B, the respective epitaxial structure (2203′, 2204′, and 2205′) has at least one etched facet (e.g., f1, f2, f3, and/or f4). In some embodiments, the etched facets (f1, f2, f3, and f4) may each have etch marks (not shown) thereon. The epitaxial structure 2204′ may include the etched facets (f2 and f3) at opposing sides, where the etched facet f2 faces the etched facet f1 of the epitaxial structure 2203′ and the etched facet f3 faces the etched facet f4 of the epitaxial structure 2205′. The epitaxial structure 2203′ has a side (e.g., left side in FIG. 12B) opposite to the etched facet f1, and the side (e.g., left side in FIG. 12B) includes a sidewall profile different from the etched facet f1. In some embodiments, the etched facet (e.g., f1, f2, f3, and/or f4) is substantially leveled (or coplanar) with the outer sidewall 205s of the underlying sidewall spacer layer 205 in the cross-sectional view. As compared to the isolation structures 301 in the first region R1, the facet of the respective epitaxial structure (2201 or 2202) may be misaligned with the outer sidewall 205s of the underlying sidewall spacer layer 205 in the cross-sectional view of FIG. 11B.

Still referring to FIG. 11B, during the removal of the bridged portions B1 of the epitaxial structures (2203, 2204, and 2205), the isolation structures 301 directly below the bridged portions B1 may be recessed to form isolation structures 301′ having recessed surfaces 301r. As compared to the isolation structures 301 in the first region R1, the respective isolation structure 301′ has additional recess (AR1, AR2) formed after the removal of the bridged portions B1. The additional recess (AR1, AR2) may be defined by the recessed surface 301r of the isolation structure 301′ which is an uneven concave curved surface. For example, the recessed surfaces 301r is “rough” in that the recessed surfaces 301r is uneven and have slopes that vary periodically or randomly across the recessed surfaces 301r. On the other hand, the top surfaces 301t of the isolation structures 301 in the first region R1 are smoother than the recessed surfaces 301r of the isolation structures 301′. For example, the cross-sectional profile of the top surfaces 301t of the isolation structures 301 in the first region R1 is a substantially semi-circular arc concaving upward in the cross-sectional view of FIG. 11B. The depths and the cross-sectional profiles of the additional recesses (AR1 and AR2) may be different and depend on the etching parameters of the etching process for removing the bridged portions B1.

Referring to FIGS. 12A-12C and with reference to FIGS. 11A-11C, the mask structure 208 may be removed. For example, the patterned mask layer 2082 is removed by, e.g., a resist stripping process or any suitable removal process. The hard mask layer 2081 may be removed through, e.g., a resist stripping process, a resist ashing process, or any suitable removal process. A cleaning process is optionally performed to clean the residuals of the mask structure 208. After removing the mask structure 208, the sidewall spacer layer 205, the mask layer 204, and the epitaxial structures (2201 and 2202) may be accessibly exposed as shown in the cross-sectional view of FIG. 12A. In the cross-sectional view of FIG. 12B, the epitaxial structures (2203′, 2204′, and 2205′), the sidewall spacer layer 205, the isolation structures (301 and 301′) may be accessibly exposed.

With continued reference to 12B-12C, a lateral distance P1 is between tops of the adjacent sidewalls 102s of the protruding portions 1024 of the semiconductor substrate 102 and measured along the first direction D1. The sidewall 102s of the protruding portion 1024 of the semiconductor substrate 102 is substantially vertical or curved corresponding to the profile of the isolation structure 301. The lateral distance P1 is smaller than 40 nm, 35 nm or 30 nm, for example. In an embodiment, the lateral distance P1 is in a range of 25 nm to 40 nm. A lateral distance P2 measured along the first direction D1 may be between the etched facet f1 of the epitaxial structure 2203′ and the etched facet f2 of the epitaxial structure 2204′, where the lateral distance P2 may be non-zero. In some embodiments, the lateral distance P2 between the etched facets (f1 and f2) is less than the lateral distance P1 between the adjacent sidewalls 102s of the semiconductor substrate 102. For example, the difference between the lateral distance P1 and the lateral distance P2 is at least about 8 nm, such as about 8 nm to about 10 nm. It is realized that the lateral distances provided herein are examples, and may be changed to other suitable values depending on process and product requirements. Similarly, the lateral distance P2 may be between the etched facet f3 of the epitaxial structure 2204′ and the etched facet f4 of the epitaxial structure 2205′, where the lateral distance P2 may be non-zero and may be less than the lateral distance P1 between the adjacent sidewalls 102s of the semiconductor substrate 102. In some embodiments, the lateral distance P2 between the etched facets (f1 and f2) is substantially equal to the lateral distance P2 between the etched facets (f3 and f4). Due to process variations or other parameters, the lateral distance P2 between the etched facets (f1 and f2) may be different from the lateral distance P2 between the etched facets (f3 and f4), according to some embodiments. In some embodiments, a maximum width W2 of the epitaxial structure 2204′ is less than a maximum width W1, W3 of the epitaxial structures 2203′ and 2205′, and the epitaxial structure 2204′ is located between the epitaxial structures 2203′ and 2205′.

Referring to FIGS. 13A-13B and with reference to FIGS. 12A-12B, an interlayer dielectric (ILD) structure 302 may be formed over the epitaxial structures 220. For example, the ILD structure 302 includes an etch stop layer 3021 lining the sidewalls of the sidewall spacer layer 205 and the exposed surfaces of the epitaxial structures 220 and a dielectric layer 3022 formed on the etch stop layer 3021. In some embodiments, the etch stop layer 3021 has a different material than the material(s) of the dielectric layer 3022. The etch stop layer 3021 may include a dielectric material (e.g., SiN, SiCN, SiOCN, or the like). For example, the etch stop layer 3021 may have a different etch rate than the material of the dielectric layer 3022. The dielectric layer 3022 may be formed of a dielectric material including phosphosilicate glass (PSG), borosilicate glass (BSG), boron-doped phosphosilicate glass (BPSG), undoped silicate glass (USG), or the like. In some embodiments, a planarization process (e.g., chemical mechanical polishing (CMP), grinding, etching back, combinations thereof, or the like) is performed on the ILD structure 302. For example, the mask layer 204 (labeled in FIG. 12A) and a portion of the ILD materials laterally adjoining the mask layer 204 are removed after the planarization process. The patterned dummy gate structure 203′ may be accessibly exposed after the planarization process.

With continued reference to 13A-13B and FIGS. 12A-12B, a removal process may then be performed to remove the patterned dummy gate structure 203′ so as to form a recess 203R. The removal process may include one or more etching steps. For example, the etching step(s) that selectively etch the patterned dummy gate structure 203′ at a faster rate than the sidewall spacer layer 205. Next, the etched first semiconductor layers 104′ may be removed by etching (e.g., isotropic etching or the like). For example, using etchants which are selective to the materials of the etched first semiconductor layers 104′, while the second semiconductor layers 106, the sidewall spacer layer 205, and the inner sidewall spacers 212 may remain relatively un-etched as compared to the etched first semiconductor layers 104′. During the step of removing the etched first semiconductor layers 104′, the epitaxial structures 220 may be protected by the ILD structure 302. After the removal of the etched first semiconductor layers 104′, respective bottom and top surfaces of each second semiconductor layers 106 and the top surface of the semiconductor substrate 102 may be exposed by recesses 104S, in the cross-sectional view of FIG. 13A.

With continued reference to FIGS. 13A-13B and FIGS. 12A-12B, a respective gate structure 240 may be formed around the second semiconductor layers 106 and fill the recesses 203R and 104S. The respective gate structure 240 may include a gate dielectric layer 244 and a gate metal layer 246 wrapping around each second semiconductor layer 106 with the gate dielectric layer 244 disposed therebetween, where the second semiconductor layers 106 (also referred to as semiconductor nanosheets or channel layers) function as channel regions. The gate dielectric layer 244 may include silicon oxide, silicon nitride, high-k dielectric, or other suitable material. For example, the gate dielectric layer 244 includes a high-k film (e.g., HfOx or the like). Other suitable dielectric material(s) may be used to form the gate dielectric layer 244. The gate metal layer 246 may include a number of sections abutted to each other, each of the gate metal sections may extend not only along a horizontal plane (e.g., the D1-D2 plane), but also along a vertical direction (e.g., the direction D3). The gate metal layer 246 may include a stack of multiple metal materials. For example, one or more work function sublayers are interposed between the gate dielectric layer 244 and the gate metal layer 246, wherein the work function sublayers may be formed separately for the n-type FET and the p-type FET which may use different metal layers.

With continued reference to FIGS. 13A-13B, the respective gate structure 240 may include an interfacial layer 242 formed between each second semiconductor layer 106 and the gate dielectric layer 244 and between the semiconductor substrate 102 and the bottommost gate dielectric layer 244. In some embodiments, the interfacial layer 242 includes an oxide-containing material such as silicon oxide, silicon oxynitride, and/or other suitable materials. In the cross-sectional view of FIG. 13A, the interfacial layer 242 may be formed on the top and bottom surfaces of each second semiconductor layer 106 and on the top surface 1021t of the respective bottom fin portion 1021 of the semiconductor substrate 102, and then the gate dielectric layer 244 is formed on the interfacial layer 242 and also formed on the sidewalls of the inner sidewall spacers 212. The gate metal layer 246 may be formed in the rest space of the respective recess 203R and 104S. In some embodiments, after sequentially depositing the materials of the gate structures 240, excess materials of the gate structures 240 may be removed by a planarization process, so that the top surface of the topmost gate structure 240 is substantially leveled (e.g., coplanar) with top surfaces of the ILD structure 302 and the sidewall spacer layers 205, within process variations. Subsequently, contact holes 320P may be formed in the ILD structure 302 to accessibly expose at least a portion of the epitaxial structures 220 for further electrical connection. For example, a portion of the dielectric layer 3022 and a portion of the etch stop layer 3021 underlying the portion of the dielectric layer 3022 are removed through one or more etching process to form the contact holes 320P. The contact holes 320P in the first region R1 or the second region R2 may have a bottom surface substantially flush with a top surface of the epitaxial structures 220 (as illustrated in the first region R1 of FIG. 13B) or recessed into the top surface of the epitaxial structures 220 (as illustrated in the second region R2 of FIG. 13B).

Referring to FIGS. 14A-14B and with reference to FIGS. 13A-13B, conductive contacts 320 may be formed in the contact holes 320P to be coupled to the epitaxial structures 220. In some embodiments, the respective conductive contact 320 includes a silicide layer 3201 overlying the epitaxial structures 220 and a contact via 3202 formed on the silicide layer 3201 and filling the contact holes 320P. For example, the silicide layer 3201 is formed on the exposed surfaces of the epitaxial structures 220 and in the contact holes 320P. The silicide layer 3201 may include a metal silicide such as titanium silicide (TiSi), nickel silicide (NiSi), and/or another type of metal silicide. The silicide layer 3201 may be included on the epitaxial structures 220 to promote adhesion between the epitaxial structures 220 and the contact vias 3202 that are to be formed in the contact holes 320P over the epitaxial structures 220, and/or to reduce contact resistance between the epitaxial structures 220 and the contact vias 3202. The silicide layer 3201 may provide the exposed surface of the epitaxial structures 220 from oxidation (e.g., native oxide growth) and/or other contamination. The respective contact via 3202 may include one or more conductive material(s), such as tungsten, copper, cobalt, ruthenium, titanium, gold, silver, alloy thereof, combinations thereof, etc. In some embodiments, a planarization process (e.g., CMP, grinding, etching back, combinations thereof, or the like) is performed on the conductive contacts 320 and the ILD structure 302, such that the top surfaces of the conductive contacts 320 and the ILD structure 302 are substantially leveled (or coplanar) with one another, within process variations.

With continued reference to FIGS. 14A-14B, a semiconductor device 100 is provided. Some variations of the semiconductor device 100 are shown in the dashed boxes (A and B). For example, in the dashed box A, the insulating layer 207 is omitted and the epitaxial structure 220 is in direct contact with the semiconductor layer 206. In the dashed box B, the insulating layer 207 and the semiconductor layer 206 are omitted and the epitaxial structure 220 is in direct contact with the top surface 102t of the semiconductor substrate 102. As shown in the cross-sectional view of FIG. 14B, the individual epitaxial structures (2203′, 2204′, and 2205′) are laterally spaced apart from one another, and the bridged portions (see “B1” labeled in FIGS. 9B and 10B) of the epitaxial structures 220 are removed to form the individual epitaxial structures (2203′, 2204′, and 2205′) having the etched facets (e.g., f1, f2, f3, and f4). The etch marks may be left on the etched facets (f1, f2, f3, and f4). The etch stop layer 3021 may conformally cover the respective epitaxial structure (2203′, 2204′, and 2205′), and the etched facets (f1, f2, f3, and f4) may be physically covered by the etch stop layer 3021.

As mentioned in the preceding paragraphs, after the removal of the bridged portions of the epitaxial structures 220 in the second region R2, the underlying isolation structures 301 may be recessed to form the additional recess (AR1, AR2). The etch stop layer 3021 may be conformally formed on the recessed surfaces 301r of the isolation structure 301′. Since the recessed surfaces 301r of the isolation structures 301′ is uneven, the etch stop layer 3021 may have a plurality of portions with varying thickness. In some embodiments, the etch stop layer 3021 has a varying thickness as a function of an orientation of the supporting surface on which the etch stop layer 3021 is deposited. For example, the thickness of the etch stop layer 3021 depends on the slope angle of a tangent (i.e. the slope angle) of the supporting surface of the isolation structures 301′ with respect to a horizontal or major plane or orientation of the underlying layer. For example, as shown in the enlarged view of the dashed box C in FIG. 14B, a portion of the etch stop layer 3021 formed on the outer sidewall 205s of the sidewall spacer layer 205 has a thickness TH1 measured along the first direction D1, and another portion of the etch stop layer 3021 formed on the bottommost point of the additional recess AR2 has a thickness TH2 measured along the third direction D3. The thickness TH2 may be greater than the first thickness TH1. In some embodiments, the thickness TH2 of the portion of the etch stop layer 3021 is greater than a thickness of another portion of the etch stop layer 3021 lining the etched facet (e.g., f1, f2, f3, or f4). The depths and the cross-sectional profiles of the additional recesses (AR1 and AR2) may be different and depend on the parameters of the etching process for removing the bridged portions of the epitaxial structures. For example, the thickness TH2 of the portion of the etch stop layer 3021 may be different from the thickness of another portion of the etch stop layer 3021 formed on the bottommost point of the additional recess AR1.

Since the cross-sectional profile of the additional recess (AR1, AR2) may vary due to process variations, portions of the dielectric layer 3022 of the ILD structure 302 extending into the additional recess (AR1, AR2) may have varying thickness. For example, a first portion of the dielectric layer 3022 of the ILD structure 302 extending into the additional recess AR1 has a thickness L1 measured along the third direction D3, and a second portion of the dielectric layer 3022 of the ILD structure 302 extending into the additional recess AR2 has a thickness L2 measured along the third direction D3. In some embodiments, the thickness L1 is greater than the thickness L2. The difference between the thicknesses (L1 and L2) may be non-zero.

Embodiments of a semiconductor device and methods for forming the same are provided. The semiconductor device includes epitaxial structures formed over the first region and the second region of the semiconductor substrate. As the feature sizes continue to decrease, the adjacent epitaxial structures (i.e. the S/D structures) of different transistors may be connected during the epitaxial process, which cause undesirable bridge problem. The bridge may cause electrical abnormalities. In some embodiments, the bridged portions of the epitaxial structures in the second region are removed to separate the epitaxial structures from one another. Therefore, the undesirable bridge problem may be eliminated. As a result, the contact resistance between the epitaxial structures and the conductive contacts overlying the epitaxial structures may be reduced, and the performance and the operation speeds of the transistors may be enhanced.

According to some embodiments, a semiconductor device includes a semiconductor substrate including a first semiconductor protrusion and a second semiconductor protrusion, a first S/D structure disposed on the first semiconductor protrusion, a second S/D structure disposed on the second semiconductor protrusion and laterally spaced apart from the first S/D structure, and a first isolation structure disposed on the semiconductor substrate and laterally interposed between the first and second semiconductor protrusions. The first isolation structure includes a recessed top surface toward the semiconductor substrate, and the recessed top surface of the first isolation structure includes slopes that vary randomly across the recessed top surface in a cross-sectional view.

According to some alternative embodiments, a semiconductor device includes a semiconductor substrate, a STI structure, a first S/D structure and a second S/D structure. The semiconductor substrate includes a first protruding portion and a second protruding portion. The first protruding portion and the second protruding portion are arranged along a first direction. The first S/D structure is disposed on the first protruding portion, and including a first etched facet. The second S/D structure is disposed on the second protruding portion, and including a second etched facet facing the first etched facet. The first etched facet and the second etched facet are respectively and substantially vertical to the first direction.

According to some alternative embodiments, a method of forming a semiconductor device includes: forming a STI structure on a semiconductor substrate, where the semiconductor substrate includes a first protruding portion, a second protruding portion, and a recessed portion laterally between the first and second protruding portions, and the STI structure is formed on the recessed portion; forming epitaxial structures over the first and second protruding portions, where the epitaxial structures include a bridged portion over the STI structure; and removing the bridge portion of the epitaxial structures to form a first S/D structure on the first protruding portion and a second S/D structure on the second protruding portion and laterally spaced apart from the first S/D structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate comprising a first semiconductor protrusion and a second semiconductor protrusion;
a first source/drain (S/D) structure, disposed on the first semiconductor protrusion;
a second S/D structure, disposed on the second semiconductor protrusion and laterally spaced apart from the first S/D structure; and
a first isolation structure, disposed on the semiconductor substrate and laterally interposed between the first and second semiconductor protrusions, the first isolation structure comprising a recessed top surface toward the semiconductor substrate, and the recessed top surface of the first isolation structure comprising slopes that vary randomly across the recessed top surface in a cross-sectional view.

2. The semiconductor device of claim 1, further comprising:
an etch stop layer conformally covering the first and second S/D structures and the recessed top surface of the first isolation structure, wherein a portion of the etch stop layer overlying the recessed top surface of the first isolation structure comprises varying thicknesses.

3. The semiconductor device of claim 1, wherein:
a first facet of the first S/D structure and a second facet of the second S/D structure face each other,
a first sidewall of the first semiconductor protrusion and a second sidewall of the second semiconductor protrusion face each other, and
a first minimum distance between the first and second facets is less than a second minimum distance between tops of the first and second sidewalls.

4. The semiconductor device of claim 1, further comprising:
a sidewall spacer layer, disposed on the first isolation structure and laterally covering the first and second semiconductor protrusions, the recessed top surface of the first isolation structure being exposed by the sidewall spacer layer.

5. The semiconductor device of claim 4, wherein:
the first S/D structure comprises a facet facing the second S/D structure,
the sidewall spacer layer comprises a sidewall intersected with the recessed top surface of the first isolation structure, and
the facet of the first S/D structure is substantially coplanar with the sidewall of the sidewall spacer layer.

6. The semiconductor device of claim 1, further comprising:
a third semiconductor protrusion and a fourth semiconductor protrusion, disposed on the semiconductor substrate;
a third S/D structure, disposed on the third semiconductor protrusion;
a fourth S/D structure, disposed on the fourth semiconductor protrusion and laterally spaced apart from the third S/D structure; and
a second isolation structure, disposed on the semiconductor substrate and laterally interposed between the third and fourth semiconductor protrusions, the second isolation structure comprising a recessed top surface toward the semiconductor substrate, and the recessed top surface of the first isolation structure being rougher than the recessed top surface of the second isolation structure in the cross-sectional view.

7. The semiconductor device of claim 6, further comprising:
a dielectric layer, being a part of an interlayer dielectric structure, wherein:
a first portion of the dielectric layer comprises a first thickness measured from a top surface of the first portion to a bottom surface of the first portion directly over a bottommost point of the recessed top surface of the first isolation structure,
a second portion of the dielectric layer comprises a second thickness measured from a top surface of the second portion to a bottom surface of the first second directly over a bottommost point of the recessed top surface of the second isolation structure, and
the first thickness is greater than the second thickness.

8. The semiconductor device of claim 1, further comprising:
semiconductor channel layers, disposed over the semiconductor substrate and vertically spaced apart from one another in another cross-sectional view; and
a gate structure, disposed between adjacent two of the semiconductor channel layers and between the semiconductor substrate and a bottommost one of the semiconductor channel layers, wherein in the another cross-sectional view, the first S/D structure is laterally connected to the semiconductor channel layers, and the gate structure is disposed between the first and second S/D structures.

9. The semiconductor device of claim 1, further comprising:
an insulating layer, vertically interposed between the first S/D structure and the first semiconductor protrusion; and
a sidewall spacer layer, disposed on the first isolation structure and laterally covering the first semiconductor protrusion, the insulating layer, and a lower portion of the first S/D structure.

10. The semiconductor device of claim 1, further comprising:
a semiconductor layer, vertically interposed between the first S/D structure and the first semiconductor protrusion; and
a sidewall spacer layer, disposed on the first isolation structure and laterally covering the first semiconductor protrusion, the semiconductor layer, and a lower portion of the first S/D structure.

11. A semiconductor device, comprising:
a semiconductor substrate, comprising a first protruding portion, a second protruding portion, wherein the first protruding portion and the second protruding portion are arranged along a first direction;
a shallow trench isolation (STI) structure, laterally between the first and second protruding portions;
a first S/D structure, disposed on the first protruding portion, and including a first etched facet; and
a second S/D structure, disposed on the second protruding portion, and including a second etched facet facing the first etched facet, wherein the first etched facet and the second etched facet are respectively and substantially vertical to the first direction.

12. The semiconductor device of claim 11, wherein a first spacing between the first and second protruding portions is greater than a second spacing between the first etched facet and the second etched facet of the first and second S/D structures.

13. The semiconductor device of claim 11, further comprising:
a sidewall spacer layer, disposed on the STI structure and laterally surrounding the first and second protruding portions; and
an etch stop layer conformally covering the first and second S/D structures, the sidewall spacer layer, and the STI structure is disposed on a recessed portion of the semiconductor substrate between the first and second protruding portions and has a the recessed top surface toward the semiconductor substrate, wherein the first S/D structure is separated from the second S/D structure by the etch stop layer, and a first portion of the etch stop layer overlying the recessed top surface of the STI structure is thicker than a second portion of the etch stop layer lining the sidewall spacer layer, wherein a facet of the first S/D structure and a sidewall of the sidewall spacer layer are substantially leveled with each other.

14. The semiconductor device of claim 13, wherein the recessed top surface of the STI structure comprises an irregular cross-sectional profile.

15. The semiconductor device of claim 13, wherein the first portion of the etch stop layer overlying the recessed top surface of the STI structure comprises segments with varying thicknesses.

16. The semiconductor device of claim 11, wherein the first S/D structure comprises a second side opposite to the first etched facet, and the second side comprises a sidewall profile different from the first etched facet.

17. The semiconductor device of claim 11, further comprising a third protruding portion extending from the semiconductor substrate, and a third S/D structure located on the third protruding portion, wherein a maximum width of the second S/D structure is less than a maximum width of the third S/D structure.

18. The semiconductor device of claim 17, wherein the second S/D structure is located between the first and third S/D structures.

19. A manufacturing method of a semiconductor device, comprising:
forming a STI structure on a semiconductor substrate, wherein the semiconductor substrate comprises a first protruding portion, a second protruding portion, and a recessed portion laterally between the first and second protruding portions, and the STI structure is formed on the recessed portion;
forming epitaxial structures over the first and second protruding portions, wherein the epitaxial structures comprise a bridged portion over the STI structure; and
removing the bridge portion of the epitaxial structures to form a first S/D structure on the first protruding portion and a second S/D structure on the second protruding portion and laterally spaced apart from the first S/D structure.

20. The manufacturing method of claim 19, wherein removing the bridge portion of the epitaxial structures comprises:
conformally forming a hard mask layer on the epitaxial structures;
forming a photoresist layer on the hard mask layer, wherein the photoresist layer comprises an opening directly over the bridge portion of the epitaxial structures; and
patterning the hard mask layer through the opening of the photoresist layer, wherein during the patterning, the bridge portion of the epitaxial structures is removed.
